(19) United States
(12) Patent Application Publication
(10) Pub. No.: US 2024/0030081 A1
(43) Pub. Date: Jan. 25, 2024

(54) SEMICONDUCTOR ASSEMBLY

(71) Applicant: TAIWAN SEMICONDUCTOR MANUFACTURING COMPANY LTD., HSINCHU (TW)

(72) Inventors: LIANG-SHIUAN PENG, TAIPEI CITY (TW); CHIH-HUNG LU, HSINCHU COUNTY (TW)

(21) Appl. No.: 17/813,637

(22) Filed: Jul. 20, 2022

(51) Int. Cl. H01L 23/31; H01L 23/58

(52) U.S. Cl. CPC H01L 23/3192; H01L 23/585

(57) ABSTRACT

A semiconductor assembly includes a semiconductor device and a seal ring. The seal ring is disposed adjacent to the semiconductor device. The seal ring includes a first side surface inclined from a top surface of the seal ring toward a bottom surface of the seal ring, wherein a lateral width of the bottom surface of the seal ring is larger than a lateral width of the top surface of the seal ring; and a first metal line disposed in the seal ring and comprising a second side surface adjacent to the first side surface of the seal ring. A maximum distance between the second side surface of the first metal line and the first side surface of the seal ring is in a range of 5 μm to 30 μm.

### TECHNICAL FIELD

The present disclosure relates in general, to semiconductor assemblies. Specifically, the present disclosure relates to semiconductor assemblies having a certain seal ring structure.

### BACKGROUND

A problem faced by conventional process is the bump bridge, since photoresist bubbles may induce photoresist micro-cracking. Bubbles form after bump photoresist coating, and can result in solder residue remaining after plating of the bump. In order to solve the problem, an improved seal ring structure would be needed.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various structures are not drawn to scale. In fact, the dimensions of the various structures may be arbitrarily increased or reduced for clarity of discussion.

FIG. 1 is top view of an array of semiconductor assemblies in accordance with some embodiments of the present disclosure.

FIG. 2A is a cross section of a portion of a semiconductor assembly in accordance with some embodiments of the present disclosure.

FIG. 2B is a cross section of a portion of a semiconductor assembly in accordance with some embodiments of the present disclosure.

FIG. 3 is a perspective top view of a portion of a semiconductor assembly in accordance with some embodiments of the present disclosure.

FIG. 4A is a cross section of a portion of a semiconductor assembly in accordance with some embodiments of the present disclosure.

FIG. 4B is a cross section of a portion of a semiconductor assembly in accordance with some embodiments of the present disclosure.

FIG. 4C is a cross section of a portion of a semiconductor assembly in accordance with some embodiments of the present disclosure.

FIG. 5A is a cross section of a portion of a semiconductor assembly in accordance with some embodiments of the present disclosure.

FIG. 5B is a cross section of a portion of a semiconductor assembly in accordance with some embodiments of the present disclosure.

FIG. 5C is a cross section of a portion of a semiconductor assembly in accordance with some embodiments of the present disclosure.

FIG. 6A is a cross section of a portion of a semiconductor assembly in accordance with some embodiments of the present disclosure.

FIG. 6B is a cross section of a portion of a semiconductor assembly in accordance with some embodiments of the present disclosure.

FIG. 7A is a cross section of semiconductor assemblies in accordance with some embodiments of the present disclosure.

FIG. 7B is a cross section of semiconductor assemblies in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90° (degree) or at other orientations) and the spatially relative descriptors used herein may likewise be interpreted accordingly.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

A semiconductor assembly may include a recess from the side surface thereof. The recess may be formed during the manufacturing process of the semiconductor assembly. The recess is formed due to photoresist bubbles in the insulation layer of the semiconductor assembly. The recess may induce micro-cracking in the insulation layer. The bubbles are formed after photoresist coating. The defect of the bubbles may result in solder residue after bump plating. Therefore, an improved seal ring structure preventing bubble/defect in the insulation layer is needed.

Some exemplary operations of semiconductor assembly formation are disclosed as follows. An exemplary seal ring is formed adjacent to the semiconductor device. Structure of the seal ring can be improve by (a) increasing the distance between a side surface of a metal line and a side surface of the semiconductor assembly, (b) using the inclined side surface of the semiconductor assembly, or (c) using the portion of the metal line exposed to the air.

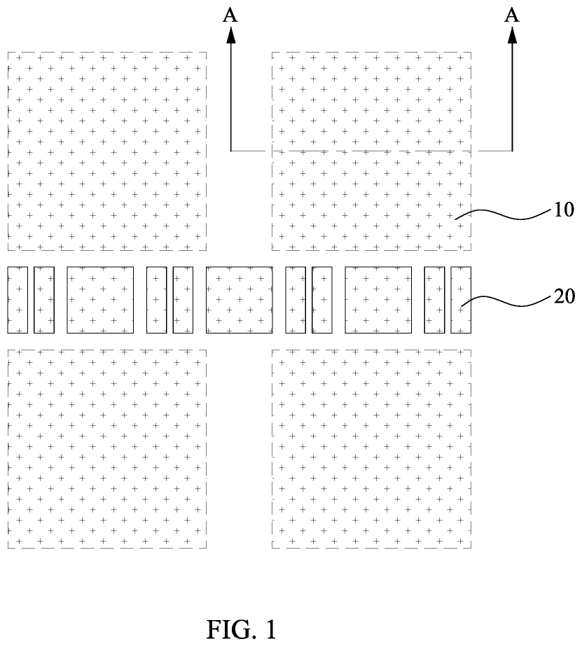

FIG. 1 is top view of an array of semiconductor assemblies 10 in accordance with some embodiments of the present disclosure. FIG. 1 shows four semiconductor assemblies 10 with metal traces 20. There are some metal traces 20 for interconnection disposed between two of the semiconductor assemblies 10. In some embodiments, the metal traces 20 include copper (Cu), tantalum (Ta), or aluminum (Al), an alloy thereof (such as AlCu), or other suitable conductive materials. In some embodiments, an assembly 10 includes a semiconductor device and a seal ring. In some embodiments, the semiconductor device may be a semiconductor chip or a semiconductor die,

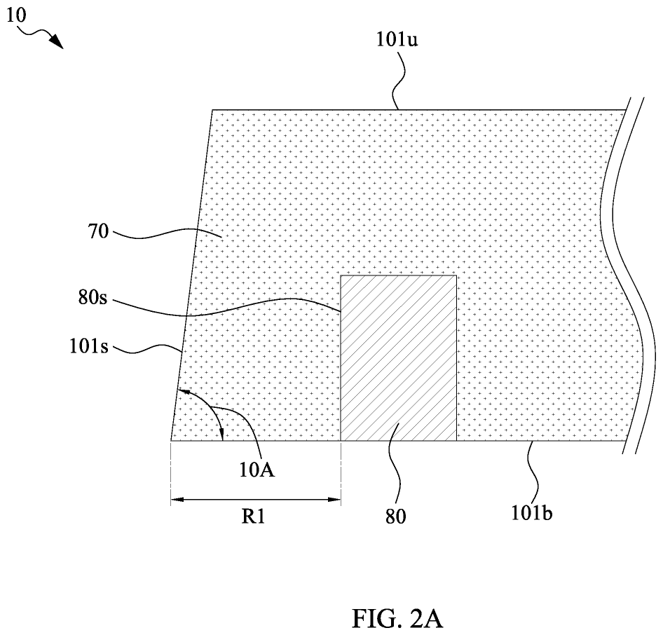

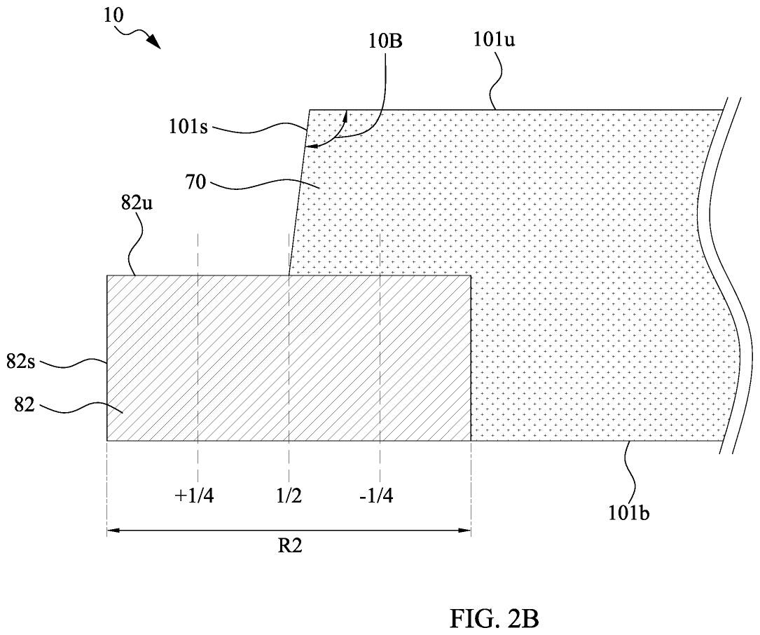

FIG. 2A is a cross section of a portion of a semiconductor assembly 10 in accordance with some embodiments of the present disclosure. In some embodiments, FIG. 2A is a cross section of a portion of the semiconductor assembly 10 taken along the line AA of FIG. 1, The semiconductor assembly 10 includes an insulation layer 70 neighboring a chip edge and a metal line 80. In some embodiments, the insulation layer 70 includes polyimide, dielectric film, organic photoresist material, or glass fiber, or other suitable materials. In some embodiments, the metal line 80 includes copper (Cu), tantalum (Ta), or aluminum (Al), an alloy thereof (such as AlCu), or other suitable conductive materials. The metal line 80 is disposed in the semiconductor assembly 10. The metal line 80 includes a side surface 80s adjacent to a side surface 101s of the semiconductor assembly 10, In some embodiments, a maximum distance R1 between the side surface 80s of the metal line 80 and the side surface 101s of the semiconductor assembly 10 is in a range of 5 micrometer (μm) to 30 μm. In some embodiments, an angle between the side surface 101s of the semiconductor assembly 10 and a bottom surface 101b of the semiconductor assembly 10 is from 20° to 85°.

FIG. 2B is a cross section of a portion of a semiconductor assembly 10 in accordance with some embodiments of the present disclosure. In some embodiments, FIG. 2B is a cross section of a portion of the semiconductor assembly 10 taken along the line AA of FIG. 1, The semiconductor assembly 10 of FIG. 2B is similar to the semiconductor assembly 10 of FIG. 2A, except for the metal line 82. The semiconductor assembly 10 includes an insulation layer 70 neighboring a chip edge and a metal line 82. In some embodiments, the insulation layer 70 includes polyimide, dielectric film, organic photoresist material, glass fiber, or other suitable materials. In some embodiments, the metal line 82 includes Cu, Ta, or Al, an alloy thereof, or other suitable conductive materials. A portion of the metal line 82 is disposed in the semiconductor assembly 10 and a portion of the metal line 82 is exposed to air. The metal line 82 includes a side surface 82s adjacent to a side surface 101s of the semiconductor assembly 10. In some embodiments, an angle 10B between the side surface 101s of the semiconductor assembly 10 and a top surface 101u of the semiconductor assembly 10 is larger than 90°. In some embodiments, a portion of the metal line 82 is disposed in the semiconductor assembly 10 and another portion of the metal line 82 is exposed to air. In some embodiments, a half of the metal line 82 is disposed in the semiconductor assembly 10 and a half of the metal line 82 is exposed to air. The metal line 82 can be divided into four portions with two portions of the metal line 82 disposed in the semiconductor assembly 10 and the other two portions of the metal line 82 is exposed to air. The side surface 82s of the metal line 82 is exposed by the side surface 101s of the semiconductor assembly 10. A first portion of a top surface 82u of the metal line 82 is covered by the semiconductor assembly 10 and a second portion of the top surface 82u of the metal line 82 is exposed to air. In some embodiments, a lateral width of the first portion of the top surface 82u of the metal line 82 is the same as a lateral width of the second portion of the top surface 82u of the metal line 82.

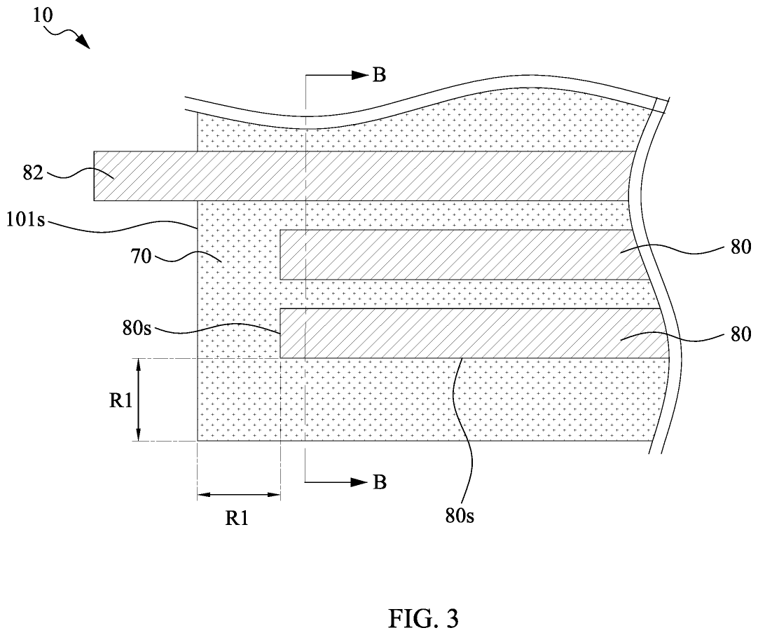

FIG. 3 is a perspective top view of a portion of a semiconductor assembly 10 in accordance with some embodiments of the present disclosure. The semiconductor assembly 10 includes an insulation layer 70 neighboring a chip edge and two metal lines 80 and a metal line 82. In some embodiments, the insulation layer 70 includes polyimide, dielectric film, organic photoresist material, glass fiber, or other suitable materials. In some embodiments, the metal lines 80 and 82 include Cu, Ta, or Al, an alloy thereof, or other suitable conductive materials. A portion of the metal line 82 is disposed in the semiconductor assembly 10 and a portion of the metal line 82 is exposed to air. The metal line 80 is disposed in the semiconductor assembly 10. In some embodiments, a distance R1 between the side surface 80s of the metal line 80 and the side surface 101s of the semiconductor assembly 10 is in a range of 5 μm to 30 μm.

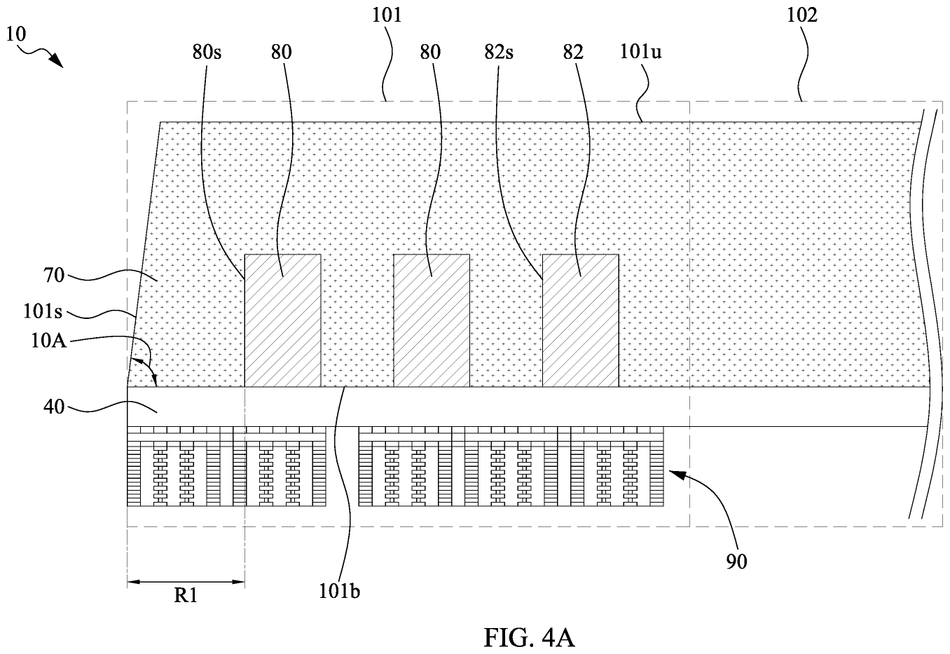

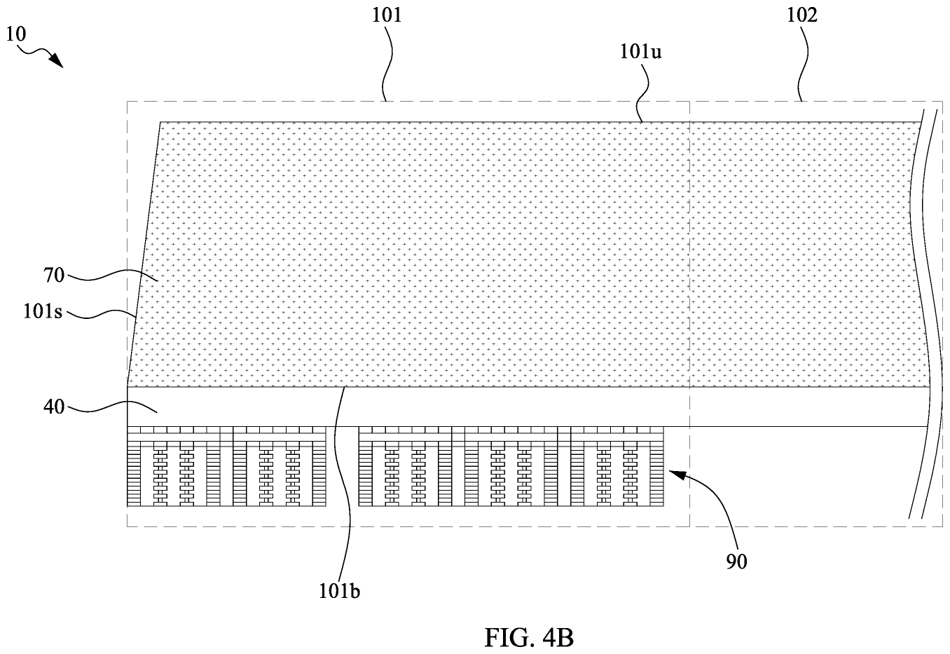

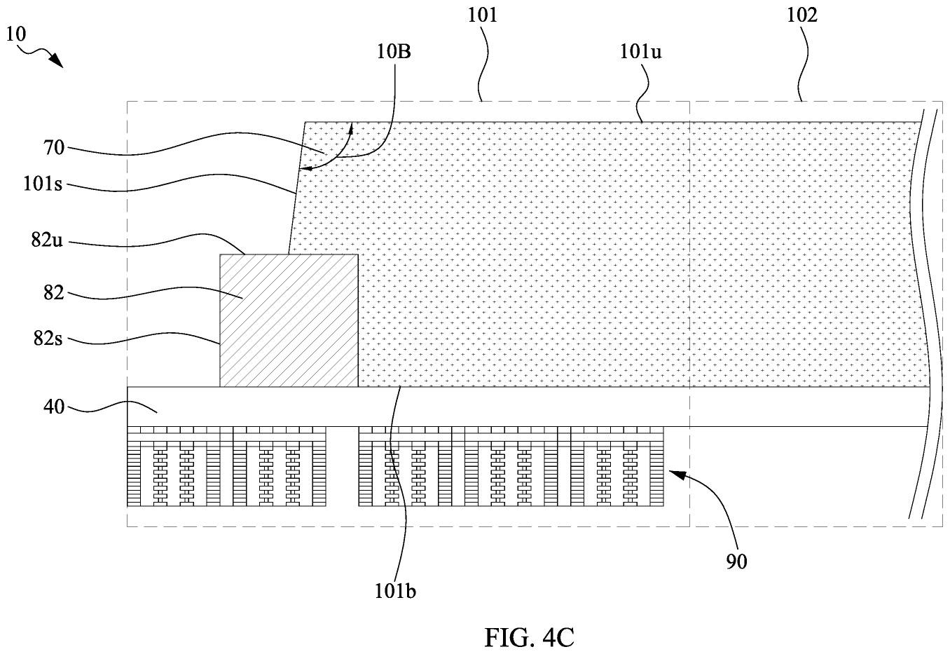

FIG. 4A is a cross section of a portion of a semiconductor assembly 10 in accordance with some embodiments of the present disclosure. In some embodiments, FIG. 4A is a cross section of a portion of the semiconductor assembly 10 taken along the line BB of FIG. 3. The semiconductor assembly 10 includes a semiconductor device 102 and a seal ring 101 disposed adjacent to the semiconductor device 102. The seal ring 101 is in contact with the semiconductor device 102. In some embodiments, the semiconductor device 102 may be a semiconductor chip or a semiconductor die. The seal ring 101 includes a side surface 101s inclined from a top surface 101u of the seal ring 101 toward a bottom surface 101b of the seal ring 101. A lateral width of the bottom surface 101b of the seal ring 101 is larger than a lateral width of the top surface 101u of the seal ring 101. In some embodiments, the seal ring 101 includes two metal lines 80 and a metal line 82. A maximum distance R1 between the side surface 80s of the metal line 80 and the side surface 101s of the seal ring 101 is from 5 μm to 30 μm. During the sawing operation, two semiconductor assemblies 10 are divided into a single semiconductor assembly 10 along a scribe line. However, sawing can damage the semiconductor assembly 10. The seal ring 101 prevents the semiconductor device 102 from the damaging during the sawing operation along the scribe line.

The structure of the seal ring 101 separates the semiconductor device 102 from the external environment. The structure of the seal ring 101 surrounds the semiconductor device 102 peripherally. The formation of the seal ring 101 is an important part in the back-end of semiconductor processes. The seal ring 101 is a stress protection structure around the semiconductor device 102 (e.g., an integrated circuits or a semiconductor chip), which protects the internal circuit inside the semiconductor device 102 from damage caused by the dicing/sawing of the semiconductor device 102 from the wafer. A typical seal ring is formed of interconnected metal lines and connecting vias. In some embodiments, the seal ring 101 may be formed as a radial shaft seal ring to protect the semiconductor device 102. In some embodiments, the seal ring 101 is conductive, but electrically isolated from the semiconductor device 102. To protect the structure of the semiconductor device 102, the seal ring 101 provides a zone in which dummy metal lines/bond pads are formed, surrounding an external area of the semiconductor device 102.

The body of the seal ring 101 includes an insulation material. The seal ring 101 includes an insulation layer 70 neighboring a chip edge and two metal lines 80 and a metal line 82. In some embodiments, the insulation layer 70 includes polyimide, dielectric film, organic photoresist material, or glass fiber, or other suitable materials. In some embodiments, the metal lines 80 and 82 include Cu, Ta, or Al, an alloy thereof, or other suitable conductive materials. A passivation layer 40 is disposed on the bottom surface 101b of the seal ring 101 and on a bottom surface of the semiconductor device 102. While in some embodiments, the passivation layer 40 includes a silicon nitride (SiNₓ) film or silicon oxide (SiO₂) film, other suitable materials may be additionally or alternatively used. An angle 10A between the side surface 101s of the seal ring 101 and the bottom surface 101b of the seal ring 101 is in a range of 20° to 85°. The metal line 80 is disposed on the passivation layer 40 and in contact with the passivation layer 40.

A redistribution layer (RDL) structure 90 is disposed below the seal ring 101. The RDL structure 90 is electrically connected to the metal line 80. In some embodiments, The RDL structure 90 is not electrically connected to other elements. The RDL structure includes at least one dielectric layer and at least one circuit layer (formed of a metal, a metal alloy, or other conductive material) in contact with or embedded in the dielectric layer. In some embodiments, the RDL structure 90 may be similar to a coreless substrate, and may be in a wafer type, a panel type, or a strip type. The RDL structure 90 may be also referred to as “a stacked structure”, “a high-density conductive structure”, or “a high-density stacked structure”. The circuit layer of the RDL structure 90 may be also referred to as “a high-density circuit layer”. In some embodiments, a density of a circuit line (including, for example, a trace or a pad) of the high-density circuit layer is greater than a density of a circuit line of a low-density circuit layer. That is, the count of the circuit line (including, for example, a trace or a pad) in a unit area of the high-density circuit layer is greater than in an equal unit area of the low-density circuit layer, such as about 1.2 times, about 1.5 times or greater, or about 2 times or greater. Alternatively, or in combination, a line width/line space (L/S) of the high-density circuit layer is less than a L/S of the low-density circuit layer, such as about 90% or less, about 50% or less, or about 20%, or less. Further, the conductive structure that includes the high-density circuit layer may be designated as the “high-density conductive structure”, and the conductive structure that includes the low-density circuit layer may be designated as a “low-density conductive structure.

FIG. 4B is a cross section of a portion of a semiconductor assembly 10 in accordance with some embodiments of the present disclosure. The semiconductor assembly 10 of FIG. 4B is similar to the semiconductor assembly 10 of FIG. 4A, except that no metal line is disposed in the seal ring 101. The semiconductor assembly 10 includes a semiconductor device 102 and a seal ring 101 disposed adjacent to the semiconductor device 102. The seal ring 101 is in contact with the semiconductor device 102. In some embodiments, the semiconductor device 102 may be a semiconductor chip or a semiconductor die. The seal ring 101 includes a side surface 101s inclined from a top surface 101u of the seal ring 101 toward a bottom surface 101b of the seal ring 101. The bottom surface 101b of the seal ring 101 is wider than the top surface 101u of the seal ring 101. A RDL structure 90 is disposed below the seal ring 101. The seal ring 101 is devoid of a metal line.

FIG. 4C is a cross section of a portion of a semiconductor assembly 10 in accordance with some embodiments of the present disclosure. The semiconductor assembly 10 of FIG. 4C is similar to the semiconductor assembly 10 of FIG. 4A, except that no metal line 80 is disposed in the seal ring 101 and a portion of the metal line 82 is exposed to air. The semiconductor assembly 10 includes a semiconductor device 102 and a seal ring 101 disposed adjacent to the semiconductor device 102. The seal ring 101 is in contact with the semiconductor device 102. In some embodiments, the semiconductor device 102 may be a semiconductor chip or a semiconductor die. The seal ring 101 includes a side surface 101s inclined from a top surface 101u of the seal ring 101 toward a bottom surface 101b of the seal ring 101. An angle 10B between the side surface 101s of the semiconductor assembly 10 and a top surface 101u of the semiconductor assembly 10 exceeds 90°. An angle 10B between the side surface 101s of the seal ring 101 and a top surface 101u of the seal ring 101 exceeds 90°.

The seal ring 101 includes a metal line 82 disposed in the seal ring 101. In some embodiments, the insulation layer 70 includes polyimide, dielectric film, organic photoresist material, glass fiber, or other suitable materials. In some embodiments, the metal line 82 includes Cu, Ta, or Al, an alloy thereof, or other suitable conductive materials. A passivation layer 40 is disposed on the bottom surface 101b of the seal ring 101 and on a bottom surface of the semiconductor device 102. While, in some embodiments, the passivation layer includes a SiNₓ film or an oxide film, other suitable materials may be additionally or alternatively used. A redistribution layer RDL structure is disposed below the seal ring 101. The RDL structure 90 is electrically connected to the metal line 82. The metal line 82 includes a side surface 82s exposed by the side surface 101s of the seal ring 101. The side surface 82s is exposed to air, A portion of the metal line 82 is exposed by the side surface 101s of the seal ring 101. A first portion of a top surface 82u of the metal line 82 is covered by the seal ring 101 and a second portion of the top surface 82u of the second metal line 82 is exposed to air. A lateral width of the first portion of the top surface 82u of the metal line 82 is the same as a lateral width of the second portion of the top surface 82u of the metal line 82.

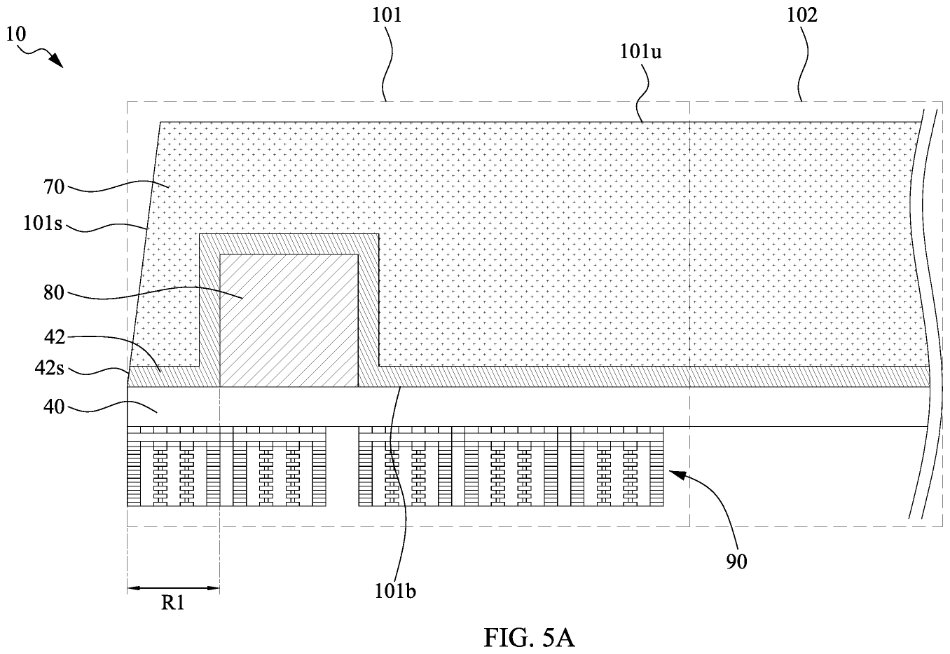

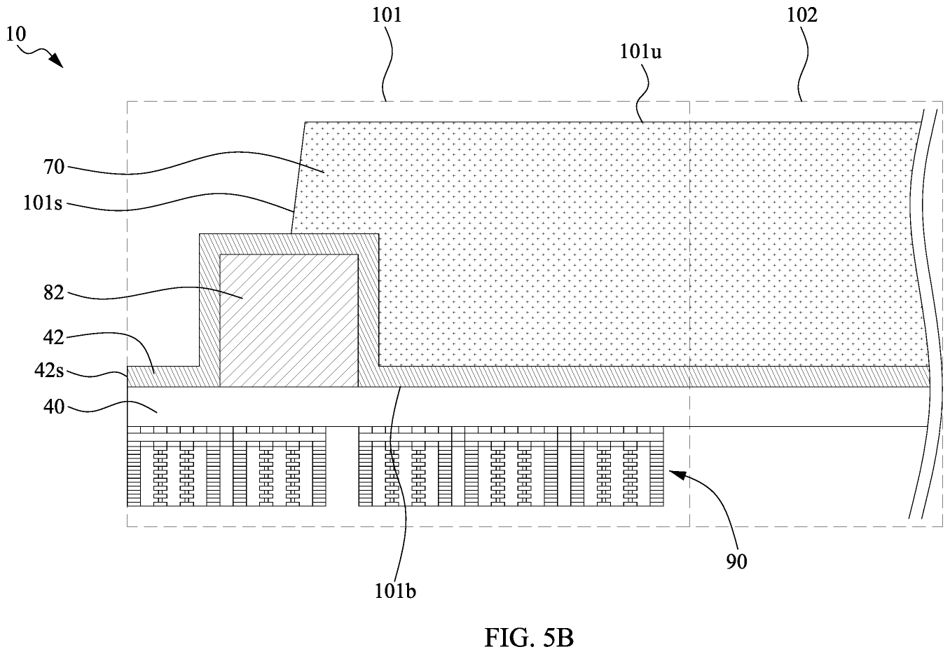

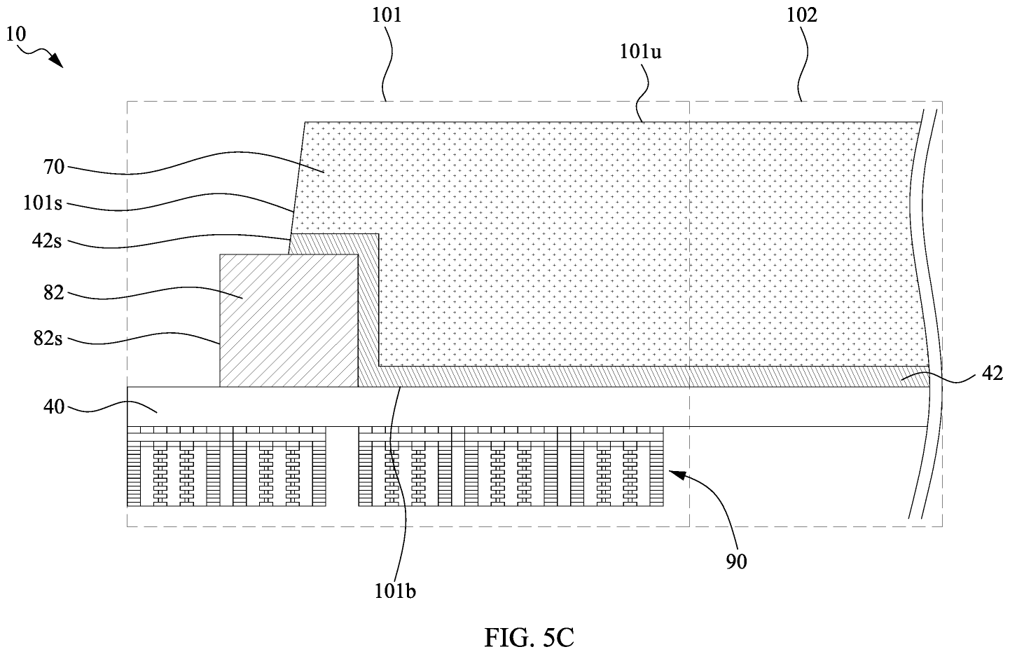

FIG. 5A is a cross section of a portion of a semiconductor assembly 10 in accordance with some embodiments of the present disclosure. The semiconductor assembly 10 includes a semiconductor device 102 and a seal ring 101 disposed adjacent to the semiconductor device 102. The seal ring 101 is in contact with the semiconductor device 102. In some embodiments, the semiconductor device 102 may be a semiconductor chip or a semiconductor die. A lateral width of the bottom surface 101b of the seal ring 101 is larger than a lateral width of the top surface 101u of the seal ring 101. In some embodiments, the seal ring 101 includes a metal line 80 disposed in the seal ring 101 and a passivation layer 40. A maximum distance R1 between the side surface 80s of the metal line 80 and the side surface 101s of the seal ring 101 is from 5 μm to 30 μm. The seal ring 101 includes a side surface 101s inclined from a top surface 101u of the seal ring 101 toward a bottom surface 101b of the seal ring 101.

The body of the seal ring 101 includes an insulation material. In some embodiments, the insulation layer 70 includes polyimide, dielectric film, organic photoresist material, glass fiber, or other suitable materials. In some embodiments, the metal line 80 includes Cu. Ta, or Al, an alloy thereof, or other suitable conductive materials. A passivation layer 40 is disposed on the bottom surface 101b of the seal ring 101 and on a bottom surface of the semiconductor device 102, A protection layer 42 is disposed on the passivation layer 40. A first portion of the protection layer 42 covers the metal line 80 and a second portion of the protection layer 42 covers the passivation layer 40. The first portion of the protection layer 42 is disposed between the insulation layer and the metal line 80. The second portion of the protection layer 42 is disposed between the insulation layer 70 and the passivation layer 40. While, in some embodiments, the passivation layer 40 and protection layer 42 include a SiNₓ film or a SiO₂ film, other suitable materials may be additionally or alternatively used. A redistribution layer MTh structure 90 is disposed below the seal ring 101. The RDL structure 90 is electrically connected to the metal line 80. The metal line 80 is disposed on the passivation layer 40 and in contact with the passivation layer 40. The protection layer 42 is disposed on the passivation layer 40. A side surface 42s of the protection layer 42 is aligned with the side surface 101s of the seal ring 101.

FIG. 5B is a cross section of a portion of a semiconductor assembly 10 in accordance with some embodiments of the present disclosure. The semiconductor assembly 10 includes a semiconductor device 102 and a seal ring 101 disposed adjacent to the semiconductor device 102. The seal ring 101 is in contact with the semiconductor device 102. In some embodiments, the semiconductor device 102 may be a semiconductor chip or a semiconductor die. In some embodiments, the seal ring 101 includes a metal line 82 disposed in the seal ring 101. A portion of the metal line 82 is exposed by the seal ring 101, The seal ring 101 includes a side surface 101s inclined from a top surface 101u of the seal ring 101 toward a bottom surface 101b of the seal ring 101. A material of body of the seal ring 101 includes an insulation material. In some embodiments, the insulation layer 70 includes polyimide, dielectric film, organic photoresist material, or glass fiber, or other suitable materials. In some embodiments, the metal line 82 includes Cu, Ta, or Al, an alloy thereof, or other suitable conductive materials.

A passivation layer 40 is disposed on the bottom surface 101b of the seal ring 101 and on a bottom surface of the semiconductor device 102. A protection layer 42 is disposed on the passivation layer 40. A first portion of the protection layer 42 covers the metal line 82 and a second portion of the protection layer 42 covers the passivation layer 40. A portion of the protection layer 42 is disposed between the insulation layer 70 and the metal line 82. A portion of the protection layer 42 is disposed between the insulation layer 70 and the passivation layer 40. The protection layer 42 is disposed on the passivation layer 40. The protection layer 42 surrounds the metal line 82 and covers a top surface of the metal line 82. The protection layer 42 includes a first portion exposed. While, in some embodiments, the passivation layer 40 and protection layer 42 include a. SiNₓ film or a SiO₂ film, other suitable materials may be additionally or alternatively used. A redistribution layer RDL structure 90 is disposed below the seal ring 101. The RDL structure 90 is electrically connected to the metal line 82. The metal line 82 is disposed on the passivation layer 40 and in contact with the passivation layer 40. The protection layer 42 is disposed on the passivation layer 40. A side surface 42s of the protection layer 42 is aligned with a side surface of the passivation layer 40.

FIG. 5C is a cross section of a portion of a semiconductor assembly 10 in accordance with some embodiments of the present disclosure. The semiconductor assembly 10 includes a semiconductor device 102 and a seal ring 101 disposed adjacent to the semiconductor device 102. The seal ring 101 is in contact with the semiconductor device 102. In some embodiments, the semiconductor device 102 may be a semiconductor chip or a semiconductor die. In some embodiments, the seal ring 101 includes a metal line 82. A portion of the metal line 82 is disposed in the seal ring 101. A portion of the metal line 82 is exposed by the seal ring 101. A portion of the metal line 82 is exposed to air. The seal ring 101 includes a side surface 101s inclined from a top surface 101u of the seal ring 101 toward a bottom surface 101b of the seal ring 101. The seal ring 101 includes an insulation material. In some embodiments, the insulation layer 70 includes polyimide, dielectric film, organic photoresist material, glass fiber, or other suitable materials. In some embodiments, the metal line 82 includes Cu, Ta, or Al, an alloy thereof, or other suitable conductive materials.

A passivation layer 40 is disposed on the bottom surface 101b of the seal ring 101 and on a bottom surface of the semiconductor device 102. A protection layer 42 is disposed on the passivation layer 40. A first portion of the protection layer 42 covers the metal line 82 and a second portion of the protection layer 42 covers the passivation layer 40. A portion of the protection layer 42 is disposed between the insulation layer 70 and the metal line 82. A portion of the protection layer 42 is disposed between the insulation layer 70 and the passivation layer 40. While, in some embodiments, the passivation layer 40 and protection layer 42 include a SiNₓ film and a SiO₂ film, other suitable materials may be additionally or alternatively used. A redistribution layer RDL structure 90 is disposed below the seal ring 101. The MTh structure 90 is electrically connected to the metal line 82. The metal line 82 is disposed on the passivation layer 40 and in contact with the passivation layer 40. The protection layer 42 is disposed on the passivation layer 40. A side surface 42s of the protection layer 42 is aligned with the side surface 101s of the seal ring 101. A portion of the metal line 82 is exposed by the protection layer 42. The side surface 82s of the metal line 82 is exposed to air.

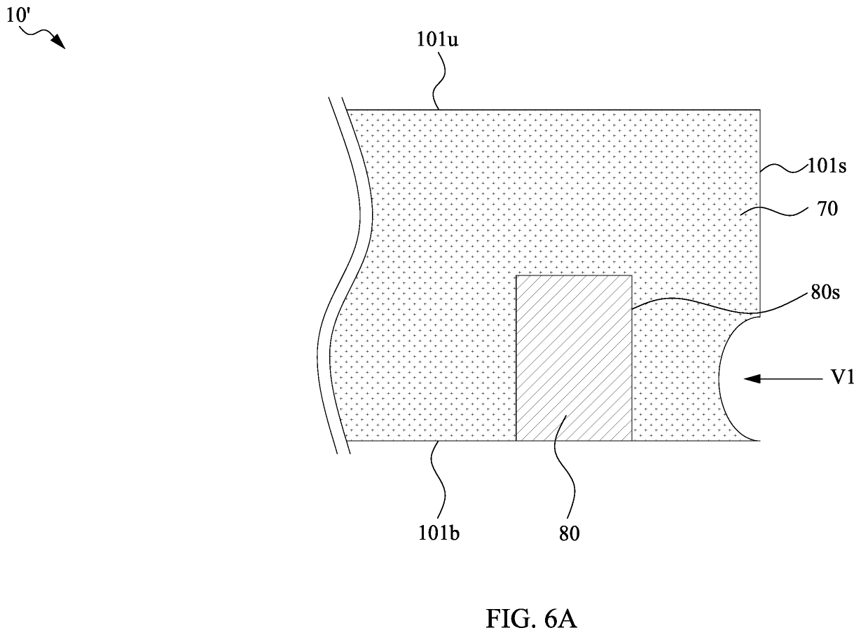

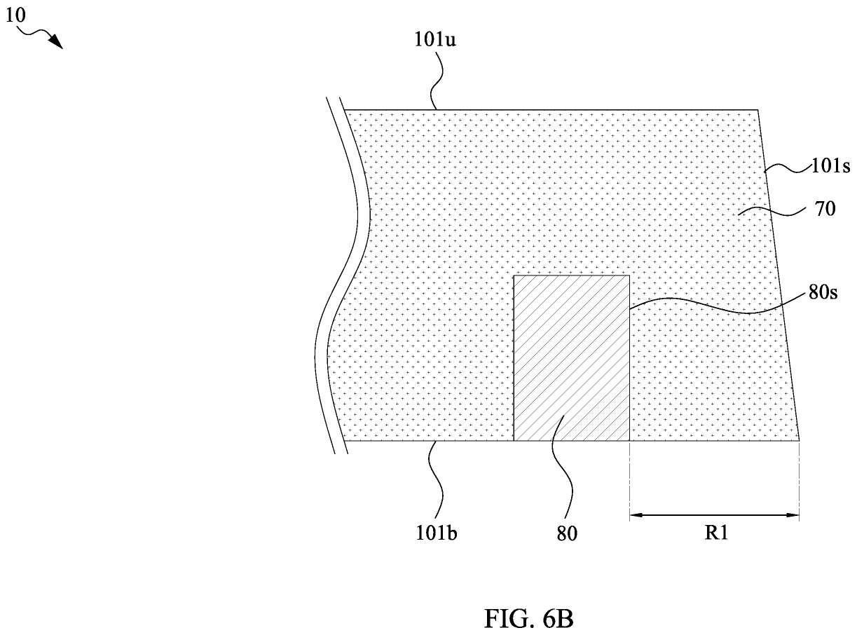

FIG. 6A is a cross section of a portion of a semiconductor assembly 10′ in accordance with some embodiments of the present disclosure. The semiconductor assembly 10′ includes a metal line 80. The metal line 80 includes Cu, Ta, or Al, an alloy thereof, or other suitable conductive materials. The semiconductor assembly 10′ includes a recess V1 from the side surface which may be formed during manufacturing process of the semiconductor assembly 10′. The recess V1 is formed due to a photoresist bubble in the insulation layer 70 and may induce micro-cracking therein. The bubbles are formed after photoresist coating. The defect of the bubbles may result in solder residues after bump plating. The bump process defect may be improved by increasing the distance between the side surface 80 of the metal line 80 and the side surface 101s of the semiconductor assembly 10′.

FIG. 6B is a cross section of a portion of a semiconductor assembly 10 in accordance with some embodiments of the present disclosure. The semiconductor assembly 10 includes a metal line 80. The metal line 80 includes Cu, Ta, or Al, an alloy thereof, or other suitable conductive materials. The side surface 101s of the semiconductor assembly 10 is inclined from a top surface 101u of the semiconductor assembly 10 toward a bottom surface 101b of the semiconductor assembly 10. The inclined side surface 101s and the distance R1 between the side surface 80s of the metal line 80 and the side surface 101s of the semiconductor assembly 10 may prevent the defect of the bubbles and improve the bubble defects. The saw quality of the scribe line adjacent to the side surface 1101s of the semiconductor assembly 10 may be improved since no solder residue exists.

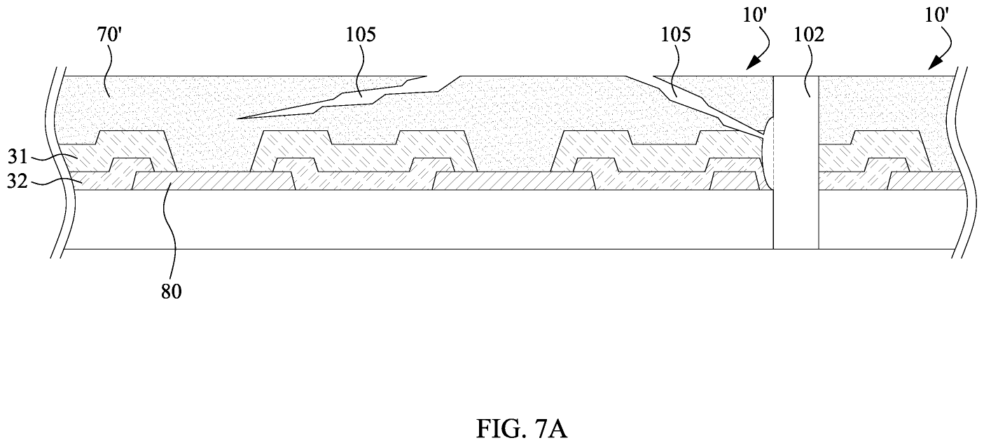

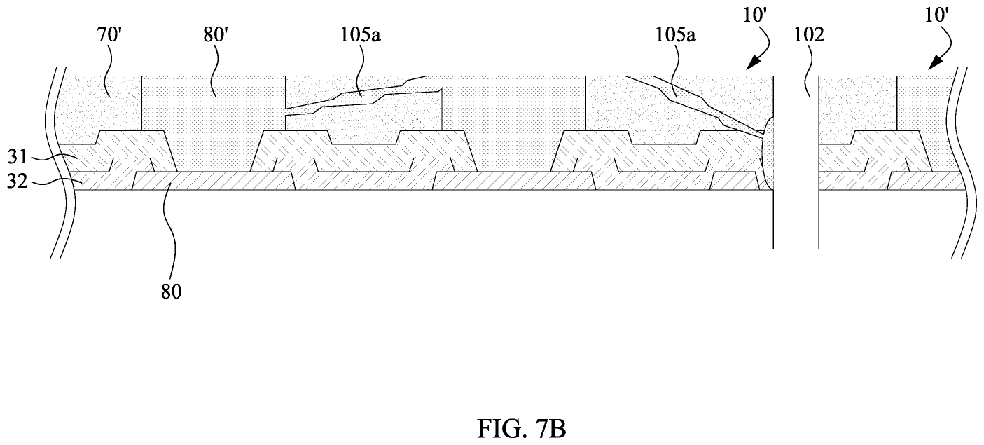

FIG. 7A is a cross section of semiconductor assemblies 10′ in accordance with some embodiments of the present disclosure. The semiconductor assembly 10′ includes an insulation layer 70′, two dielectric layers 31 and 32 and metal lines 80. The scribe line 102 is disposed between two semiconductor assemblies 10′. In some embodiments, the metal line 80 includes Cu, Ta, or Al, an alloy thereof (such as AlCu), or other suitable conductive materials. In some embodiments, the insulation layer 70′ includes polyimide, dielectric film, organic photoresist material, or glass fiber, or other suitable materials. In some embodiments, the dielectric layers 31 and 32 include a SiNₓ film, a SiO₂ film; however, other suitable materials may be additionally or alternatively used in some embodiments, the side surface of the semiconductor assembly 10′ includes a recess adjacent to the two dielectric layers 31 and 32. The recess may be formed during the manufacturing process of the semiconductor assembly 10′. The recess is formed due to a photoresist bubble in the insulation layer 70′. The recess may induce the micro-cracking 105 in the insulation layer 70′. The bubbles are formed after photoresist coating. The micro-cracking 105 may affect the forming of the conductive bumps.

FIG. 7B is a cross section of semiconductor assemblies 10′ in accordance with some embodiments of the present disclosure. The semiconductor assembly 10′ includes an insulation layer 70′, two dielectric layers 31 and 32, metal lines 80, and two metal bumps 80′. In some embodiments, the metal line 80 include Cu, Ta, or Al, an alloy thereof (such as AlCu), or other suitable conductive materials. In some embodiments, the metal bumps 80′ include a solder material, or other suitable conductive materials. In some embodiments, the insulation layer 70′ includes polyimide, dielectric film, organic photoresist material, or glass fiber, or other suitable materials. In some embodiments, the dielectric layers 31 and 32 include a SiNₓ film, a SiO₂ film; however, other suitable materials may be additionally or alternatively used. In some embodiments, the recess adjacent to the two dielectric layers 31 and 32 would be filled into a solder material by a plating process. The micro-cracking 105 in the insulation layer 70′ would be filled into the solder material after the plating process. The metal material 105a would be the solder (metal) residues. The metal material 105a may affect the forming of the conductive bumps. The metal material 105a results in the short of the two adjacent bumps 80′. The defect may result in the solder residues 105a after bump plating.

According to some embodiments, a semiconductor assembly includes a semiconductor device and a seal ring. The seal ring is disposed adjacent to the semiconductor device. The seal ring includes a first side surface inclined from a top surface of the seal ring toward a bottom surface of the seal ring, wherein a lateral width of the bottom surface of the seal ring is larger than a lateral width of the top surface of the seal ring; and a first metal line disposed in the seal ring and comprising a second side surface adjacent to the first side surface of the seal ring. A maximum distance between the second side surface of the first metal line and the first side surface of the seal ring is from 5 μm to 30 μm.

According to other embodiments, a semiconductor assembly includes a semiconductor device and a seal ring. The seal ring is disposed adjacent to the semiconductor device. The seal ring includes a first side surface inclined from a top surface of the seal ring toward a bottom surface of the seal ring, wherein an angle between the first side surface of the seal ring and the top surface of the seal ring is larger than 90°; and a second metal line comprising a third side surface, wherein the third side surface is exposed by the first side surface of the seal ring.

According to some embodiments, a semiconductor assembly includes a semiconductor device and a seal ring. The seal ring is disposed adjacent to the semiconductor device. The seal ring includes a first side surface inclined from a top surface of the seal ring toward a bottom surface of the seal ring, wherein a lateral width of the bottom surface of the seal ring is larger than a lateral width of the top surface of the seal ring; and a RDL structure disposed below the seal ring, wherein the seal ring is devoid of a metal line.

The methods and features of the present disclosure have been sufficiently described in the above examples and descriptions. It should be understood that any modifications or changes without departing from the spirit of the present disclosure are intended to be covered in the protection scope of the present disclosure.

Moreover, the scope of the present application in not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, may be utilized according to the present disclosure.

Accordingly, the appended claims are intended to include within their scope: processes, machines, manufacture, compositions of matter, means, methods or steps. In addition, each claim constitutes a separate embodiment, and the combination of various claims and embodiments are within the scope of the present disclosure.

What is claimed is:

1. A semiconductor assembly comprising:
a semiconductor device; and
a seal ring disposed adjacent to the semiconductor device, wherein the seal ring comprises:
a first side surface inclined from a top surface of the seal ring toward a bottom surface of the seal ring, wherein a lateral width of the bottom surface of the seal ring is larger than a lateral width of the top surface of the seal ring; and
a first metal line disposed in the seal ring and comprising a second side surface adjacent to the first side surface of the seal ring;
wherein a maximum distance between the second side surface of the first metal line and the first side surface of the seal ring is in a range of 5 micrometer (μm) to 30 μm.

2. The semiconductor assembly of claim 1, wherein an angle between the first side surface of the seal ring and the bottom surface of the seal ring is in a range of 20° (degree) to 85°.

3. The semiconductor assembly of claim 1, wherein the seal ring further comprises a second metal line disposed in the seal ring, wherein the second metal line comprises a third side surface exposed from the first side surface of the seal ring.

4. The semiconductor assembly of claim 3, wherein a first portion of a top surface of the second metal line is covered by the seal ring and a second portion of the top surface of the second metal line is exposed to air.

5. The semiconductor assembly of claim 4, wherein a lateral width of the first portion of the top surface of the second metal line is the same as a lateral width of the second portion of the top surface of the second metal line.

6. The semiconductor assembly of claim 4, further comprising a passivation layer disposed on the bottom surface of the seal ring.

7. The semiconductor assembly of claim 6, wherein the first contact with the passivation layer.

8. The semiconductor assembly of claim 6, further comprising a protection layer disposed on the passivation layer, wherein a first portion of the protection layer covers the first metal line and a second portion of the protection layer covers the passivation layer.

9. The semiconductor assembly of claim 6, further comprising a protection layer disposed on the passivation layer, wherein a fourth side surface of the protection layer is aligned with the first side surface of the seal ring.

10. The semiconductor assembly of claim 9, wherein a portion of the second metal line is exposed from the protection layer and wherein the third side surface of the second metal line is exposed to air.

11. The semiconductor assembly of claim 6, further comprising a protection layer disposed on the passivation layer, wherein the protection layer surrounds the second metal line and covers a top surface of the second metal line, and wherein the protection layer comprises a first portion exposed to air.

12. The semiconductor assembly of claim 1, further comprising a redistribution layer (RDL) structure disposed below the seal ring, wherein the RDL structure is electrically connected to the first metal line.

13. The semiconductor assembly of claim 1, wherein a material of the seal ring includes an insulation material.

14. A semiconductor assembly comprising:
a semiconductor device; and
a seal ring disposed adjacent to the semiconductor device, wherein the seal ring comprises:
a first side surface inclined from a top surface of the seal ring toward a bottom surface of the seal ring, wherein an angle between the first side surface of the seal ring and the top surface of the seal ring is larger than 90°; and
a second metal line comprising a third side surface, wherein the third side surface is exposed by the first side surface of the seal ring.

15. The semiconductor assembly of claim 14, wherein a first portion of a top surface of the second metal line is covered by the seal ring and a second portion of the top surface of the second metal line is exposed to air.

16. The semiconductor assembly of claim 15, wherein a lateral width of the first portion of the top surface of the second metal line is the same as a lateral width of a second portion of the top surface of the second metal line.

17. The semiconductor assembly of claim 14, further comprising a passivation layer disposed on the bottom surface of the seal ring.

18. The semiconductor assembly of claim 17, further comprising a protection layer disposed on the passivation layer, wherein a fourth side surface of the protection layer is aligned with the first side surface of the seal ring.

19. The semiconductor assembly of claim 18, wherein a portion of the second metal line is exposed from the protection layer and wherein the third side surface of the second metal line is exposed to air.

20. A semiconductor assembly comprising:
a semiconductor device; and
a seal ring disposed adjacent to the semiconductor device, wherein the seal ring comprises:
a first side surface inclined from a top surface of the seal ring toward a bottom surface of the seal ring, wherein a lateral width of the bottom surface of the seal ring is larger than a lateral width of the top surface of the seal ring; and
a redistribution layer (RDL) structure disposed below the seal ring, wherein the seal ring is devoid of a metal line.
